(19) United States
(12) Patent Application Publication
(10) Pub. No.: US 2003/0223597 A1
(43) Pub. Date: Dec. 4, 2003

(54) Adapative noise compensation for dynamic signal enhancement

(76) Inventors: Sunil Puria, Mountain View, CA (US); William Kerry Keal, Santa Clara, CA (US)

Correspondence Address: HAYNES BEFFEL & WOLFELD LLP, P O BOX 366, HALF MOON BAY, CA, 94019, US

(21) Appl. No.: 10/157,598

(22) Filed: May 29, 2002

(51) Int. Cl. H03G 3/00

(52) U.S. Cl. 381/104; 381/107

(57) ABSTRACT

The present invention includes methods and devices useful for dynamic gain control. Particular aspects of the present invention are described in the claims, specification and drawings.

### BACKGROUND OF THE INVENTION

1. Field of the Invention

The present invention relates to the field of enhanced sound reproduction, and particularly to adaptive compensation for environmental or background sounds.

2. Description of Related Art

Many devices use a volume control to adjust an audio output level. Use of a volume control to set linear amplification is a compromise at best. It is a compromise between not “too loud” for high-level signals and not “too soft” for low-level signals. Because the compromise depends on specific conditions, such as specific signal material and background noises, it is common to adjust the volume control repeatedly.

Various approaches have been taken to adjusting the output level of audio systems for listening in noisy conditions. One situation is where the signal and the noise are mixed and the problem of separating the two is of primary concern. U.S. Pat. No. 6,157,670, by Kosanovich, entitled “Background Energy Estimator,” is one example. In some situations, such as traveling in an automobile, both signal levels, such as an electrical signal from the radio, and signal-plus-noise-levels, such as from a microphone in the cabin, are available. U.S. Pat. No. 5,872,852, by Dougherty, entitled “Noise Estimating System for Use with Audio Reproduction Equipment,” may be relevant. Still, estimating the power spectrum of the noise is problematic. In some instances, the appropriate gain is pre-estimated based on the noise level. The Dougherty '852 patent and U.S. Pat. No. 6,198,830, by Holube et al., entitled “Method and Circuit for Amplification of an Input Signal of a Hearing Aid,” are examples. In other instances, the user is presented with a number of presets and selects a predefined set of gain adjustments based on their listening environment. The Dougherty '852 patent, U.S. Pat. No. 6,055,502,by Kitamura, entitled “Adaptive Audio Signal Compression Computer System and Method,” and U.S. Pat. No. 6,104,822 by Melason and Linderman, entitled “Digital signal processing hearing aid” may be relevant.

Four patents that independently measure both signal and noise levels include: U.S. Pat. No. 5,553,134, by Allen et al., entitled “Background Noise Compensation in a Telephone Set;” U.S. Pat. No. 5,615,270, by Miller et al., entitled “Method and Apparatus for Dynamic Sound Optimization;” U.S. Pat. No. 6,011,853, by Koski et al., entitled “Equalization of Speech Signal in Mobile Phone;” and U.S. Pat. No. 5,907,823, by Sjoberg et al., entitled “Method and Circuit Arrangement for Adjusting the Level or Dynamic Range of an Audio Signal.” Three of these patents involve applications to telephones and the fourth deals with a car radio. Telephones and car radios have been the focus of most past research. Two of the patents use multiband compression to improve comprehensibility.

Typical approaches to measuring signal level have used finite impulse response (FIR), infinite impulse response (IIR) or fast Fourier transform (FFT) methods to estimate and smooth the noise in frequency bands as a function of time. These approaches impose substantial computational requirements.

Therefore, there is an opportunity to provide streamlined methods of estimating background signal levels that impact gain adjustment.

### SUMMARY OF THE INVENTION

The present invention includes methods and devices useful for dynamic gain control of audio. Particular aspects of the present invention are described in the claims, specification and drawings.

### BRIEF DESCRIPTION OF THE DRAWINGS

FIG. 1 depicts measurement of noise levels.

FIGS. 2A-B show noise power in frequency bands as a function of time for La Columbia restaurant, after smoothing.

FIG. 3 is a flowchart of an adaptive noise compensation combined with a compressor.

FIG. 4 shows three Gaussian and Butterworth filters with various center frequencies.

FIG. 5 illustrates the operation of an if-then-else smoothing filter.

FIGS. 6-9 demonstrate the effect of varying parameters on smoothing time constants.

FIGS. 10A-B show an example of estimated noise power based on interpolation from sub bands.

### DETAILED DESCRIPTION

The following detailed description is made with reference to the figures. Preferred embodiments are described to illustrate the present invention, not to limit its scope, which is defined by the claims. Those of ordinary skill in the art will recognize a variety of equivalent variations on the description that follows.

Dynamic gain adjustment allows a system to adapt to the varying background noise. This is useful in virtually any system that reproduces an audio signal. Dynamic adjustments can vary across the audio spectrum, for instance boosting high frequency sounds more than mid-frequency sounds. The appropriate gain in each band depends on background noise or audio levels and on the loudness of the desired audio signal in a corresponding band.

These inventors have observed that dynamic gain adjustment should not take place with every sample, may benefit from different attack and release times, and can be based on limited sampling of selected frequency bands. These observations derive from hearing science, as much as from digital signal processing.

In one embodiment, the present method relies on a separate background or noise signal channel as a basis for estimating the background audio. Background signal estimates are calculated for a few bands. The overall character of the background signal is extrapolated from these few sample points. The extrapolated background signal strength estimates serve as a basis for gain control in a plurality of bands. A volume compressor or a linear equalizer can be controlled, corresponding to the extrapolated background signal strength estimates. When a volume compressor is used, a compression ratio is selected based on background audio or noise. The selected compression ratio allows the compressor to squeeze the dynamic range of an input signal into an audible dynamic range. The audible dynamic range may be affected by the background noise or by the other factors, such as the listener's hearing thresholds. The combination of background noise and listener hearing threshold may be calculated in real time, applying any algorithm for combining the two influences that is desired, such as the algorithms described in the commonly owned application, U.S. patent application Ser. No. 10/104,364, by Hannes Muesch, Brent W. Edwards and Sunil Puria, “Alternative Sound Track for Hearing-Handicapped Users and Stressful Environments”, which application is hereby incorporated by reference.

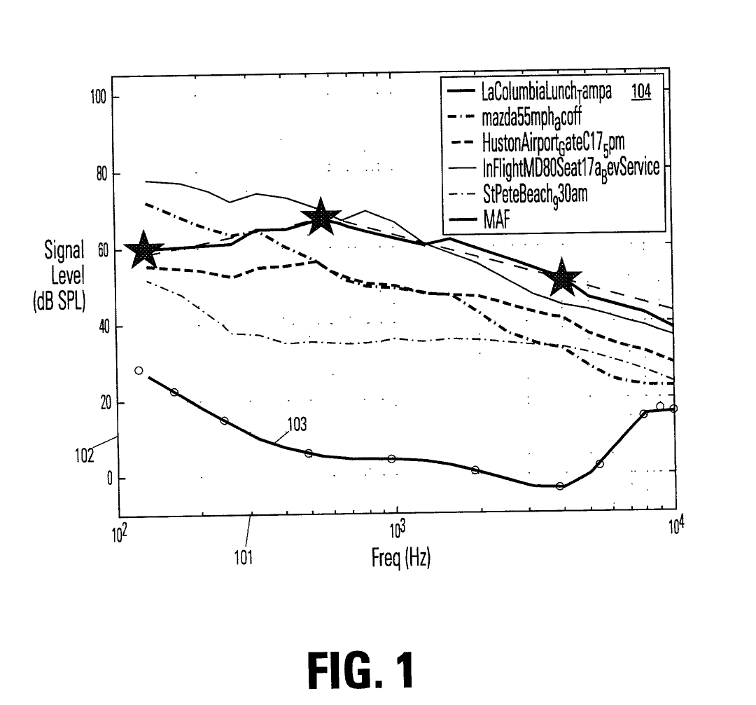

Measurement of noise in a variety of public places indicates that the noise does not vary independently across frequency bands, as depicted in FIG. 1 below. This suggests that measurement in a few subbands can be extrapolated to all bands. Extrapolating from a few subbands to a larger number of bands for gain control significantly reduces computational requirements.

There are many approaches to measuring the noise power in a given subband. These include FFT methods and time-domain filtering methods. In the FFT methods, the result is a single number for a given block of data, while in the time-domain methods the result is obtained for every data sample, which is then down-sampled to the desired FFT block rate. Compressors that use FFT methods operate on blocks of data, which favors measuring subband noise in time blocks. One approach is to compute a discrete Fourier transform (DFT) at the desired subband frequencies. However, auditory filters in the human ear and multiband compressors have a much wider bandwidth than the signal frame of the DFT. A window can be applied to an input signal to adapt the DFT to the desired bandwidth. The design of the window depends on the desired bandwidth, which in turn depends on the center frequency. Several window types allow adjustment of parameters, including Gaussian and modified Kaiser windows, or any other window that allows control of the bandwidth of the filter.

Inefficient noise power smoothing can be combined with other aspects of the present invention. To reduce short time scale changes to the signal due to variations in noise, there are several potential smoothing approaches. Typically, linear FIR filters are used. An if-then-else alternative is described below, which uses a logical test of the difference between current and past samples and adds or subtracts a step increment of signal level, responsive to the differences. Different step increments for increasing and decreasing signal level effectively separate attack and decay times.

Measurements of noise level shown in FIG. 1. The horizontal axis 101 reflects signal frequency in Hz. The vertical axis 102 represents signal level, measured in dB sound pressure level. An audibility threshold 103 (minimum audible field or MAF) is plotted below the measured noise signals. The means of noise power integrated in third octave bands from five different locations are shown; the locations are identified in the legend 104. The quietest location measured is St. Pete Beach with an approximate level range of 50-58 dBA (A-Weighted SPL) while the loudest is in flight (MD80 airplane) with a level of 86-87 dBA. LaColumbia Restaurant noise was 73-75 dBA. For reference, standard conversation level, in a very quite place, tends to be about 65 dBA. All noise measurements were sampled at 44.1 kHz.

FIG. 1 shows that the mean noise, at a given location, is a smooth function of frequency. In other words, the noise in any given frequency band is not independent of the noise in a neighboring frequency band. In fact, the entire noise curve can be estimated from measurements in two or preferably three frequency bands, as indicated by the stars at approximately 130, 550 and 4000 Hz. The noise in bands other than the measured bands can be estimated by extrapolation.

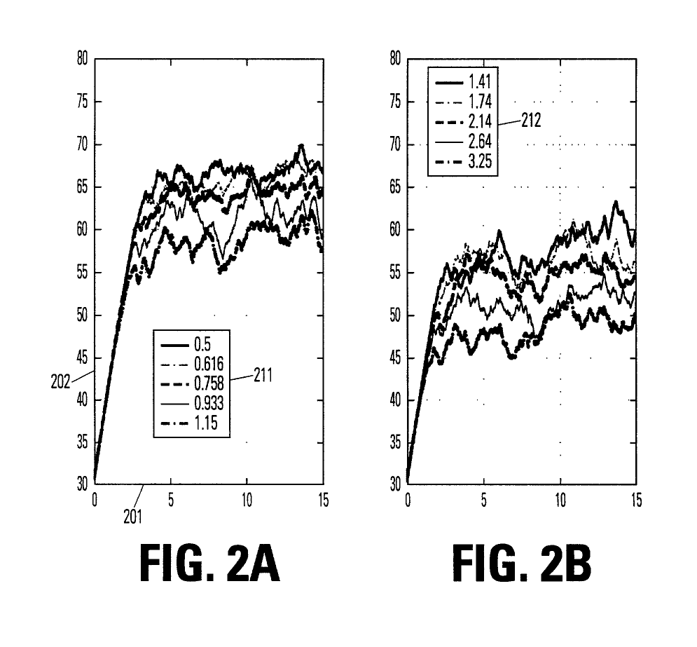

FIGS. 2A-B show noise power in frequency bands as a function of time for La Columbia restaurant, after smoothing. The horizontal axis of these figures represents time in seconds. The vertical axis represents power in dB. In the left-hand figure, the legend 211 indicates five sound frequencies that were sampled. Similarly, in the right figure, the legend 212 indicates five additional sound frequencies that were sampled. The noise shown in FIG. 2 was down-sampled to 8 kHz to simulate telephony bandwidth. FIG. 2 shows that even as a function of time, the average noise in adjacent frequency bands does not vary independently but rather tends to be co-modulated by common underlying mechanisms. It is believed that when events occur, signals in all frequency bands are generated at the same time. Furthermore, noise also gets filtered through common mechanisms. Common filtering mechanisms include propagation through air, reflections (eg., walls) and room reverberation. For example, when one analyzes the noise from the beach one finds that peak noise, across frequency bands, tends to occur at the same time. That is, the noise power in all bands builds up and reaches a maximum as the wave crashes on the beach. The noise power in all the bands then decays and the cycle is repeated.

co-dependence of noise across frequency bands is contrary to generally accepted textbook notions that noise in frequency bands is statistically independent. FIG. 1 also shows that noise power is not white either. Above about 0.5 kHz, noise power in 1/3 octave bands tends to vary with the ratio one/frequency. Below 0.5 kHz, the shape of the noise curve depends on the environment. The auditory system seems to be able make use of the co-modulation in noise. It is well known that threshold for tones in noise increases as the bandwidth of the noise increases. But, through a phenomena called co-modulation masking release (CMR), the threshold decreases after the bandwidth is increased past the critical bandwidth.

These basic observations can be used to increase the computational efficiency of an adaptive gain control. Most algorithms take an FFT of the noise and calculate the noise power in all bands. FIGS. 1 & 2 show that it is not necessary to compute the noise power is all frequency bands. By computing noise in a few bands and extrapolating to other bands, significant computational savings can be achieved.

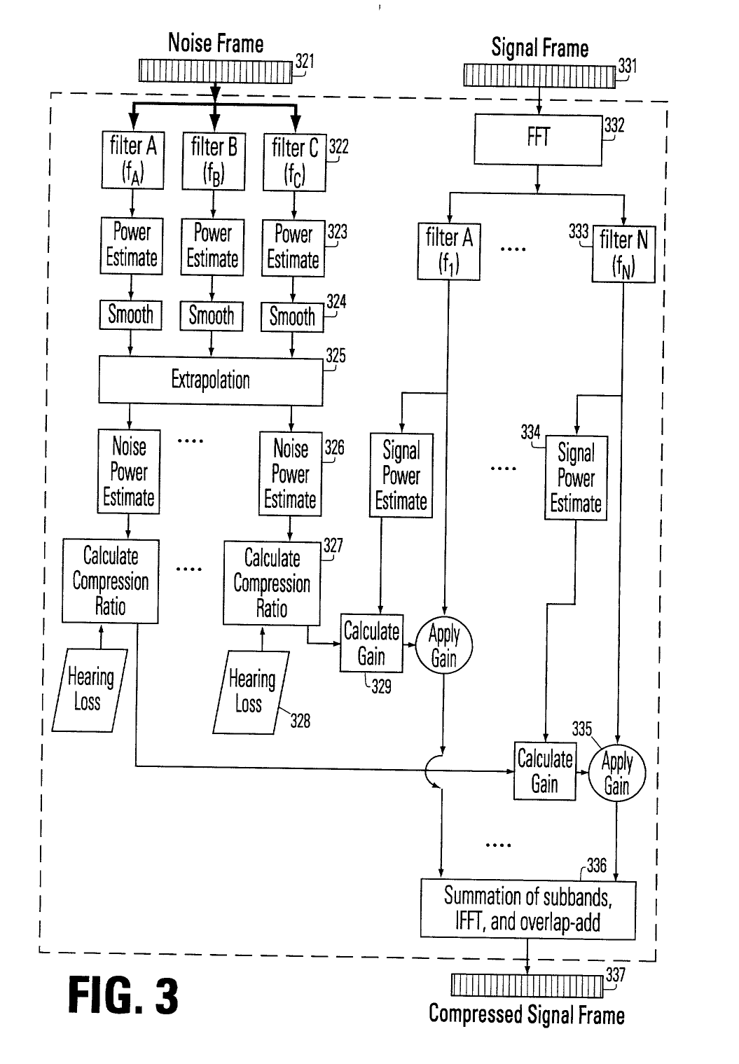

FIG. 3 is a flowchart that illustrates an adaptive noise control combined with a compressor that samples noise at three center frequencies. Thick lines in the diagram indicate vector variable paths while thin lines indicate scalar variable paths. The input to the algorithm is a frame of noise 321 and a frame of signal 331. The output is a compressed signal frame 337. Another optional input is a hearing loss profile 328, based on an individualized or generalized hearing profile. The compressor uses multi-band compression. The number of bands in the signal channel depends on the application. For example, one might use 12 bands for mobile phone applications whereas music applications may require 20 bands. The noise is analyzed in three frequency bands 322. For some applications, two frequency bands might be satisfactory. For other applications, more than three frequency bands might be used. The noise power in these bands is estimated 323. This diagram depicts smoothing 324 prior to extrapolation 325, which is computationally efficient, because there are fewer channels to smooth. Alternatively, extrapolated noise power estimates 326 could be smoothed prior to calculation compression ratios 327 or calculation of gain parameters 329. The calculation of compression ratios and gain factors may optionally take into account a hearing loss profile 328. On the compressor side of this flowchart, the signal frame 331 is subjected to the fast Fourier transform 332 and filters are applied to the outputs of the fast Fourier transform in N channels. Signal power estimates are calculated for the N channels 334. Gains are applied 335 to the signal channels, taking into account the extrapolated the background or noise, and the strength of the signal. The N channels of gain-adjusted signal are recombined by summation, overlap adding and application of an inverse fast Fourier transform 336. A compressed signal frame 337 is output. While FIG. 3 illustrates a digital implementation of signal compression, dynamic gain control could be applied to an analog implementation instead of a digital implementation or to a linear equalizer instead of the compressor.

Digital compression using a fast Fourier transform-based algorithm involve a frame or block processing. That is, signals are processed one frame at a time, not one sample at a time. Frame-based processing reduces the number of estimates of noise power that are required. This is much different from past applications of FIR filters to estimate noise power, as FIR filters estimate noise power at every sample, which estimates are decimated and smoothed. Thus, use of FIR filters not only requires numerous computations, but also requires decimation and smoothing steps.

An efficient method for estimating noise power at a few center frequencies of a frame is application of the discrete Fourier transform (DFT) to the noise frame at desired frequencies. Effectively, this application of the discrete Fourier transform is like multiplying a rectangular window of known narrow bandwidth by the noise frame.

Measured noise power in the noise channel is used to estimate the amount of masking that takes place in each auditory filter band, due to background noise. Calculation of effective masking in auditory filter bands is improved by estimating noise power in bandwidths corresponding to auditory filters. Since auditory filters are approximately constant Q, the bandwidth of auditory filters increases with the filter center frequency.

Estimation of noise level around the center frequencies 322 requires a different bandwidth for each noise filter. One way to increase the bandwidth of a computed DFT is to multiply the noise frame with a window before taking the DFT. This approach makes use of the leakage property of windows. Generally speaking, windows are designed to minimize leakage. That is, the less leakage there is, the narrower the bandwidth of the window. Reversing the normal application of windows, one can design windows that have specified, wide bandwidths. There are several window functions that allow specification of the window bandwidth. Examples of these include the recursive Gaussian windows, described by Shera, C. A. and G. Zweig (1993). “Noninvasive Measurement of the Cochlear Traveling-Wave Ratio,” Acoust Soc Am 93(6):3333-5, and the modified Kaiser window. Gaussian windows are well-suited, because the discrete Fourier transform is also Gaussian. The shape of a Gaussian window in the time and frequency domains looks the same. Another characteristic of the Gaussian window is that it provides minimal ringing.

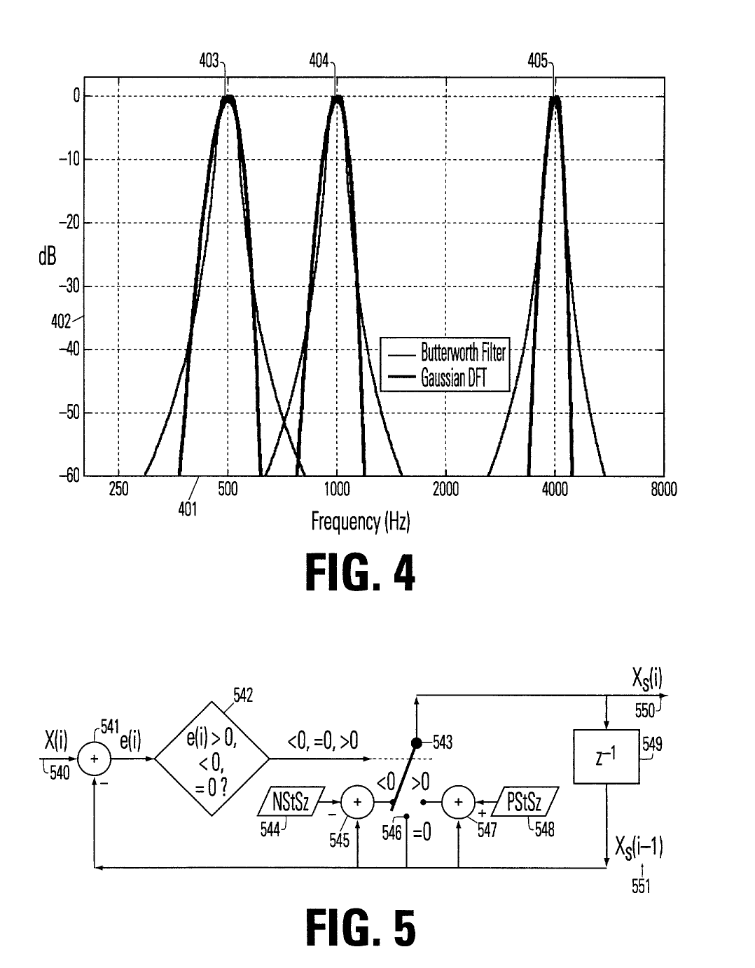

FIG. 4 shows three Gaussian filters with center frequencies of 0.5, 1 and 4 kHz, labeled 403, 404, 405. The horizontal axis 401 represents frequency in Hz. The vertical axis 402 represents power in dB. The filter bandwidths increase as a function of center frequency. The frequency responses of the three Butterworth filters, with same parameters as the Gaussian filters, are not very different from the frequency responses of the Gaussian filters. The Gaussian filters tend to have a greater slope and are sharper than the Butterworth filters.

Power in band-limited signals is defined as the (PSD) power spectral density (VA [symbol] 2/Hz) times the bandwidth (Hz). For discrete signals, power is the sum of square of the spectral level within a specified bandwidth from i=1 to M:

$$P = {\sum }_{i = 1}^{M} {\vert X ( {f}_{i} ) \vert}^{2}$$

Where fᵢ is a discrete frequency within the desired band.

The window DFT method of computing the spectral level integrates across the frequency bandwidth, as part of the DFT calculation. It is unnecessary to sum up the frequency bins, due to the property that the windowed power spectrum is equal to the power spectrum of the signal convolved with the spectrum of the window. The convolution operation is effectively like an integration, or summation, operation.

The power estimated in the desired bandwidth is an approximation to the actual power. Power is sometimes defined as the sum-of-the square of the PSD components, as depicted in the equation directly above. In the convolution/integration operation stated above, we obtain the square of the sum of the components. Strictly speaking, the two are different. But, the expected values of the two terms are approximately the same, because the cross-product of the Fourier transforms integrate to zero due to orthonormal basis functions of the Fourier transform operation. The power estimation procedure exploits this property to approximately calculate the power in the increased bandwidth. FIG. 2 shows an example of the power computed using the Window-DFT method in several bands. Although not shown here, the power estimated with other methods (FFT, IIR, etc.) is comparable to the Window-DFT method.

Power estimates typically are smoothed, so gain parameters will not change too rapidly. Several characteristics are desirable for the noise smoothing algorithm. First, the time constants should be on the order of seconds. Second, the attack and decay times should be independently settable. Finally, the smoothing algorithm should be efficiently implemented on DSP chips, including integer chips.

One typical approach to smoothing power is with standard linear filters, such as IIR. These methods are computationally inefficient, when applied with long time constants, because long time constants require filter coefficients with great precision and are highly susceptible to quantization errors. To reduce quantization errors, it is typical to low-pass filter and decimate before applying the smoothing filter. This increases complexity and computational requirements.

Simple first order IIR filter can be written as follows:

Xₛ(i)=X(i)+a*Xₛ(-1)

Where Xₛ(i) is a current estimation and Xₛ(i-1) is a prior estimation. In the above IIR filter the output is the sum of the current input and scaled past input.

A more efficient filter can be constructed using a threshold (zero or non-zero) and if-then-else logic. A filter can be specified as follows:

$$\begin{matrix}IF e ( i ) > Th , \\ {X}_{s} ( i ) = {X}_{s} ( i - 1 ) + PStSz \\ ELSEIF e ( i ) < - Th , \\ {X}_{s} ( i ) = {X}_{s} ( i - 1 ) - NStSz \\ ELSE \\ {X}_{s} ( i ) = {X}_{s} ( i - 1 ) \\ END\end{matrix}$$

Where e(i)=Xs(i)-Xs (i-1) and Th is the error threshold which effectively creates a deadband. Here, Xs(i-1) is an adjusted prior signal estimate, to which the filter may have been applied to limit the amount of adjustment in one step. This threshold can be zero or non-zero. Different thresholds can be applied for increasing and decreasing signal strength, Th1 and Th2, by extension of this logic.

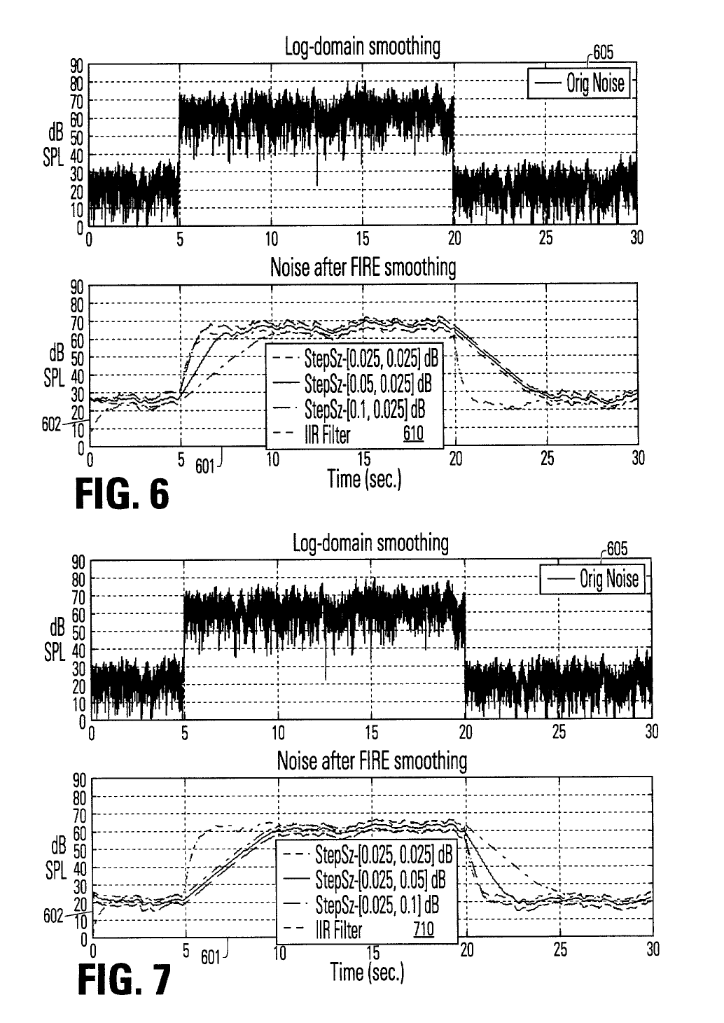

This smoothing filter is illustrated in FIG. 5. Applying this filter, the change in output, for every time sample, is constant. That is, a step change is applied to the filter, at every sample, so that the output may catch up with the input. The step change can either be positive (PStSz) or negative (NStSz) depending on the sign of the error signal (e). Alternatively, PStSz and NStSz may follow a set of rules that depend on the size of the error signal (e).

FIG. 5 illustrates the operation of the smoothing filter when the threshold Th=0. In can readily be modified to take into account a nonzero threshold. The smoothing filter operates on two samples, a current sample that is input 540 and a prior output sample 551. The difference between the current input and prior output samples is calculated 541 to produce an error term e(i). This error term is logically tested 542 to determine whether the difference is positive, negative or 0. Alternatively, this error term could be logically tested to determine whether the difference is within positive and negative thresholds, greater than the positive threshold or less than the negative threshold. Of course, the positive and negative thresholds can be the same. The thresholds and step sizes may be configurable, for instance, by the user or by presets. The result of the test 542 controls operation of the switch 543. In one case, a negative step size 544 is added 545 to the prior output sample 551. In another case 546, the prior sample value is unchanged. In the third case, a positive step size 548 is added 547 to the prior output sample 551. The result of the operation 543 is output 550 and also buffered 549 for processing of the next sample. In contrast to this method, IIR filters require multiplications and additions that are proportional to the number of filter coefficients and may require decimation to achieve the desired time constants due to quatization issues. This smoothing filter can be implemented with a single addition for each time step. This requires less computation than linear filter approaches and is readily implemented on DSP chips.

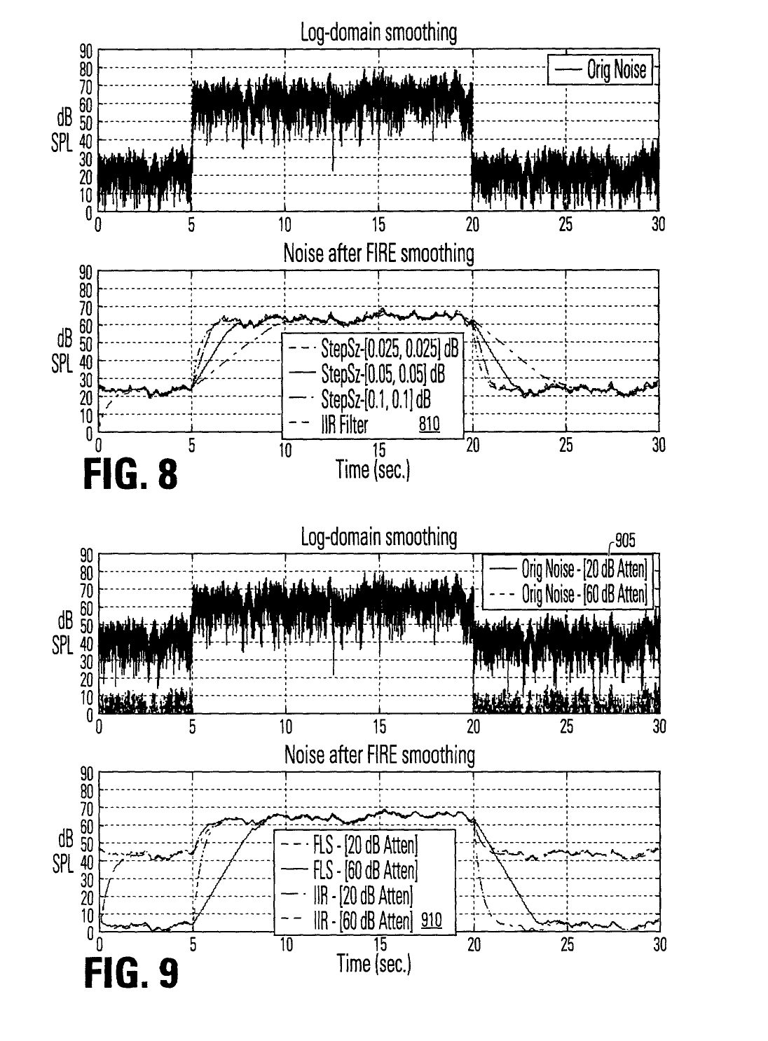

FIGS. 6-9 demonstrate the effect of varying values of the parameters PStSz and NStSz on smoothing time constants. One advantage of this smoothing logic is that adjusting the values of NStSz and PStSz can modify the attack and decay times of the smoothing algorithm. The smoothing in these figures is performed on a log amplitude (dB) scale. It could, alternatively, be performed on a non-log scale. In each figure, the if-than-else smoothing filter response is compared to the response from an IIR filter. For the IIR filter, the noise was low-pass filtered, decimated and smoothed using a two second settling time for the IIR smoothing filter.

FIG. 6 shows the effect of increasing and decreasing parameter PStSz by a factor of two, while maintaining NStSz constant. The horizontal axis 601 represents time in seconds. The vertical axis 602 represents signal level in dB. The top graph in FIG. 6 represents the original noise 605. The bottom graph depicts the effect of four different smoothing filters 610, three of them if-than-else filters and the fourth an IIR filter. FIG. 6 illustrates an inverse relationship between step size and the time it takes the smoothing algorithm to go from a low level to a high level steady state signal (onset settling time). For the onset settling time, the if-then-else filter shows a similar response to the IIR filter when PStSz is about 0.1 dB. The offset settling time of the if-then-else algorithm, in this example, is longer than the IIR filter.

FIG. 7 shows, in a similar fashion to FIG. 6, that there is also an inverse relationship between the time it takes to go from a high level to a low level (offset settling time) and NStSz. Different parameters for step size 710 are shown in this figure. For the offset settling time, the if-than-else filter shows a similar response to the IIR filter when NStSz is about 0.1 dB. For smaller step sizes the settling time is longer. In FIGS. 6 and 7, it can be observed the steady state value seems to depend on the step sizes used for smoothing. Differences of about 2 dB in the steady state value are seen.

FIG. 8 shows the effect of changing both PStSz and NStSz. Three curves 810 are shown corresponding, in a similar way to FIGS. 6 and 7, to the baseline (0.05 dB), an increase by a factor of two (0.1 dB) and a decrease by a factor of two (0.025 dB). The onset and offset settling times are symmetric. Furthermore, the steady state value no longer depends on the step sizes used. With PStSz and NStSz equal to 0.1 dB, the response is very similar to that of an IIR filter response.

Finally, the effect of signal level on onset and offset settling time is shown in FIG. 9. The same filter parameters 910 were used to process both input noise signals. When the input noise level difference is 20 dB, the onset and offset settling times are about 2 seconds. When the input noise level difference is 60 dB, both settling times are about 4 seconds. As expected, for the IIR filter the settling time is about 2 seconds for both input signals. FIG. 9 demonstrates that linear filters (eg., IIR filters) have time constants that are level independent and if-than-else smoothing filters have time constants that are level dependent.

Examples from hearing sciences where time constants depend on level are abundant. Physiology of hearing teaches us that the time constants in the medial olivocochlear (MOC) system depend on level. See, (Liberman, M. C., S. Puria and J. J. Guinan, Jr. (1996); “The Ipsilaterally Evoked Olivocochlear Reflex Causes Rapid Adaptation of the 2F1-F2 Distortion Product Otoacoustic Emission.” J Acoust Soc Am 99(6):3572-84. This means that the time constant of the feedback to the cochlea, mediated by synapses of MOC neurons onto outer hair cells, depends on the level of the signals in the contralateral ear, ipsilateral ear, or both ears. The level-dependent time constants of the if-then-else smoothing filters mimic biological processes, which may have advantages over linear filters.

Once the noise power is estimated in frequency bands, for instance using the windowed-DFT method described above, and smoothed, the noise power at frequency bands needed for gain control are estimated. The estimating function can be fit to the measured noise power (e.g., in Three bands) by any number of well-known methods. The estimating function can be a generalized function or it can be a specific function based on expected characteristics of background or noise in the environment where the system will function. Potential methods of fitting a function include linear interpolation and the spline interpolation. The resulting estimates can be used to determine the gain factor applicable to a compressor, linear equalizer or other system.

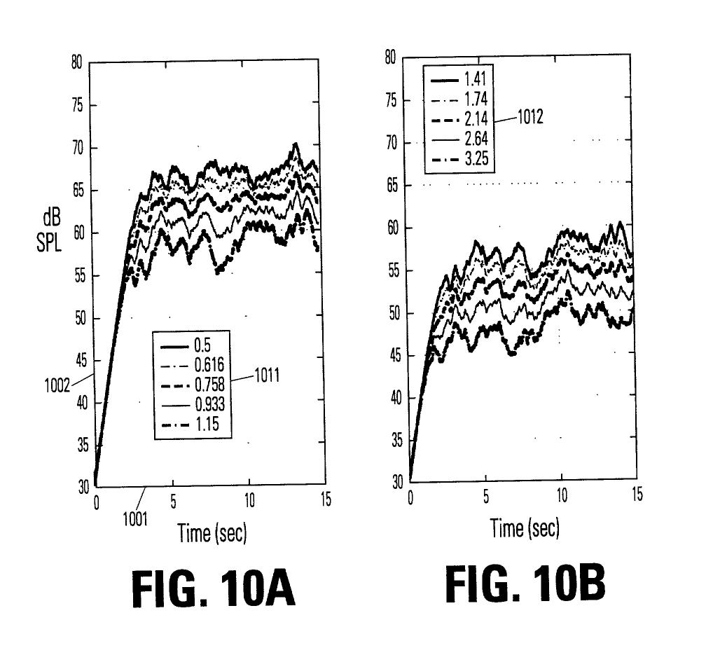

FIGS. 10A-B show an example of the noise power estimated by the methods described above. The horizontal axis 1001 represents time in seconds. The vertical axis 1002 represents signal level in dB. Noise was calculated at frequencies 0.5, 1.125 and 3.25 kHz, corresponding to fA, fB, fC, (322) and extrapolated to the frequencies listed in the legends 1011, 1012. There is good agreement between the noise power calculated at the band frequencies and noise power estimated. This suggests that computational requirements can be reduced without sacrificing accuracy.

In one embodiment, the interpolated noise power is fed to an algorithm that determines the compression ratio (or equivalently alpha) for a full spectrum dynamic compression algorithm. Compression ratios and power levels, in frequency bands f1 to fN of the current signal frame, are then used to determine the gain applied to the signal frame.

An article of manufacture practicing aspects of the present invention may include a program recording medium on which a program is impressed that carries out the methods described above. It may be program transmission medium across which a program is delivered that carries out the methods described above. It may be component supplied is an accessory to enhance another audio device, carrying out the methods described above, such as a motherboard or feature. It may be a logic block available for incorporation in a signal processing system that carries out the methods described above.

While the present invention is disclosed by reference to the preferred embodiments and examples detailed above, it is understood that these examples are intended in an illustrative rather than in a limiting sense. It is contemplated that modifications and combinations will readily occur to those skilled in the art, which modifications and combinations will be within the spirit of the invention and the scope of the following claims.

We claim as follows:

1. A method of adaptive multiband gain control, responsive to a background audio signal, the method including:
receiving a signal representing the background audio signal; estimating signal power of the background audio signal in n subbands, where n>=2; and
extrapolating from the n subband signal power estimates to m subband gain control signal power estimates, where m>n.

2. The method of claim 1, further including adjusting a multiband gain control corresponding to the m subband gain control signal power estimates.

3. The method of claim 1, wherein the background audio signal is environmental noise.

4. The method of claim 1, wherein the step of estimating signal power includes applying a windowed discrete Fourier transform.

5. The method of claim 4, wherein a window size for the windowed discrete Fourier transform is chosen to control the effective bandwidth of the noise estimate.

6. The method of claim 4, wherein the window is a Gaussian window.

7. The method of claim 4, wherein the window is a modified Kaiser window.

8. The method of claim 1, wherein n=2.

9. The method of claim 1, wherein n=3 and m>=12.

10. The method of claim 1, further including smoothing the signal power of the estimates for the m or n subbands.

11. The method of claim 10, wherein the step of smoothing includes applying a step change to a sample if a current signal power estimate differs from a previous signal power estimate by more than a threshold tolerance.

12. The method of claim 11, wherein different step sizes are applied to increasing and decreasing signal power estimates.

13. The method of claim 11, wherein the different threshold tolerances are applied to increasing and decreasing signal powers.

14. The method of claim 10, wherein the step of smoothing includes applying a filter:
If e(i)>Th1, then Xs(i)=Xs(i-1)+PStSz
ElseIf e(i)<-Th2, then Xs(i)=Xs(i-1)−NStSz
Else Xs(i)=Xs(i) end;
wherein e(i) is the difference between a current signal power input estimate (Xs(i)) and an adjusted prior signal power estimate (Xs(i-1)), PStSz is a positive step size, and NStSz is a negative step size.

15. The method of claim 14, wherein Th1=Th2.

16. The method of claim 14, wherein PStSz ? NStSz.

17. The method of claim 2, wherein adjusting includes application of multiband audio compression.

18. The method of claim 2, wherein adjusting includes multiband linear equalization.
